(19) United States
(12) Patent Application Publication
(10) Pub. No.: US 2001/0004489 A1
(43) Pub. Date: Jun. 21, 2001

(54) Printed circuit boards with solid interconnect and method of producing the same

(76) Inventor: Chua Ah Lim, Singapore (SG)

Correspondence Address: Paul T. Dietz, Esq., NIKOLAI, MERSEREAU & DIETZ, P.A., 820 International Centre, 900 Second Avenue South, Minneapolis, MN, 55402-3813, US

(21) Appl. No.: 09/761,347

(22) Filed: Jan. 16, 2001

(30) Foreign Application Priority Data
Feb. 4, 1999 (SG) 9900806-2

(51) Int. Cl. H05K 1/11

(52) U.S. Cl. 428/209; 174/264; 427/97; 205/125; 428/309.9

(57) ABSTRACT

A printed circuit board with a solid metallic interconnect which gives a stable and effective electrical interconnection between metallic layers separated by one or more dielectric layers. The method of producing the interconnect includes creating the solid metallic interconnect by metallic plating on the base copper at the interconnecting location, followed by the lamination of the appropriate dielectric layer. This dielectric layer may have a pre-cut hole corresponding to the solid metallic interconnect, which is registered with the interconnect before lamination. A layer of dielectric polymer is then removed from the interconnect by traditional methods. This is followed by electroplating and conventional metallization and circuitry formation. This process may also be applied to create an interconnect spanning more than one dielectric layer.

The present application is an application filed in accordance with 35 U.S.C. §119 and claims the benefit of earlier filed Singapore application number 9900806-2 filed on Feb. 4, 1999.

### I. FIELD OF THE INVENTION

The present invention relates to printed circuit boards. In particular, the present invention relates to methods of producing interconnects in a single or multiple layer printed circuit board or substrate.

### II. BACKGROUND OF THE INVENTION

A printed circuit board having a rigid, flexible, single, double or multilayer board has found important uses in the semi-conductor and electronic industry. A printed circuit board typically contains at least one dielectric layer with one or both sides of the board metallized to form circuitry. Interconnections between the layers of metallic circuitry are often required such that the various metallic layers may communicate with each other electrically.

Conventional methods of fabricating a printed circuit board with interconnects requires the use of lasers or mechanical drills. This mechanical method may be useful for forming interconnecting holes, which span the entire depth of the various layers of the printed circuit board. For “blind” holes, which only span one or more core or dielectric layers but not all layers, controlled depth drilling is required. However, mechanically controlling the depth of drilling is extremely difficult to perform reliably, and therefore not widely used. Another known method for fabricating a printed circuit board with blind holes utilizes sequential lamination where cladded cores are mechanically drilled and plated before laminating all the cores to form a multi-layer printed circuit board. When the diameter of the blind hole is small, using mechanical drilling becomes difficult, and laser drilling is preferred.

When utilizing a laser for frilling, a laser beam is used to form the hole before plating is performed on the hole such that electrical connection is formed. A CO₂ laser is typically used to drill the hole in the dielectric layer, wherein the hole is used for the interconnection of layers. Although the CO₂ laser effectively cuts through polymeric resins, a CO₂ laser does not effectively cut through metal. Thus, use of a CO₂ laser for drilling holes is particularly useful when forming blind holes of a controlled depth by providing a metallic layer below the dielectric layer in which the hole is to be formed. After the hole is drilled through the dielectric or core layer, electrolysis plating or electroplating is performed to plate the metallic surface of the hole to provide electrical connection. However, an indentation is typically left in the plated hole, which is undesirable, since it can easily trap contaminants, and also occupy previous space on that surface, as useful landscape cannot be made directly on the indentation.

One known method to solve this indentation problem is to use solder paste or other electrically conductive paste to close the hole and also to serve as a composite interconnect. U.S. Pat. No. 5,817,404 to Kawakita et al. describes the use of an electrically conductive paste containing electrically conductive particles and a thermosetting resin to fill the holes after laser drilling. The paste, however, may sustain cracks during the multiple lamination process to form different layers of the board. The cracks may be sustained because the paste is typically a composite of various materials, which have different coefficients of expansion. Repeated cycles of heating and cooling may create internal cracks in the composite material, or stresses along the plating of the hole, affecting the effectiveness of the electrical interconnection. The present invention overcomes these and other disadvantages, which will become apparent to those skilled in the art from a review of the description of the invention.

### OBJECT OF THE INVENTION

It is an object of the present invention to provide a printed circuit board interconnect that overcomes the above-identified shortcomings.

It is another object of the present invention to provide a printed circuit board with an interconnect of solid metal.

It is a further object to provide a method of making a printed circuit board with a solid metallic interconnect.

### SUMMARY OF THE INVENTION

The present invention provides for a solid metallic interconnect in printed circuit board, which gives a stable and effective electrical interconnection between metallic layers separated by one or more dielectric layers. The interconnect of the present invention is constructed of a solid metal, thereby avoiding potential cracking caused by differences in a composite material. The solid metallic interconnect is defined as an interconnection made of solid metal, as opposed to interconnects made of composite material. Without limitation, the solid metal may include copper, copper with a thin layer of other metal such as gold, or metal alloy. A “composite material” may include solder paste and other electrically conducting particles mixed with resin.

A method of producing the interconnect of the present invention includes the steps of creating the solid metallic interconnect by metallic plating on a base copper at the interconnecting location, followed by a lamination of the appropriate dielectric layer. This dielectric layer may have a pre-cut hole corresponding to the solid metallic interconnect, which is aligned or registered with the interconnect before lamination. Alternatively, the solid interconnect may be used to pierce through the dielectric layer. Yet another alternative is to use a liquid or wet-type dielectric, which can be applied to the base copper. A layer of dielectric polymer is then removed from the interconnect by traditional methods. This is followed by electroplating and conventional metallization and circuitry formation. This same process may also be used to interconnect multiple layers, wherein the interconnect may span more than one dielectric layer.

### BRIEF DESCRIPTION OF THE DRAWINGS

FIGS. 1A-1E are a series of sectional side elevational views showing in series a conventional method for producing an interconnect between a dielectric layer.

FIGS. 2A-2G are a series of sectional side elevational views showing in series one method according to the present invention for producing solid metallic interconnects of a printed circuit board.

FIGS. 3A-3E are a series of sectional side elevational views showing in series an alternate method according to the present invention for producing solid metallic interconnects of a printed circuit board.

FIGS. 4A-4D are a series of sectional side elevational views showing in series an alternate method according to the present invention for producing solid metallic interconnects of a printed circuit board.

FIG. 5 shows a multi-layered printed circuit board constructed in accordance with the method of the present invention.

FIGS. 6A-6H are a series of sectional side elevational views showing in series an alternate method according to the present invention for producing solid metallic interconnects of the present invention incorporated into a printed circuit board.

### DESCRIPTION OF THE INVENTION

The solid metallic interconnect according to the present invention may be produced from a solid metal such as copper such that not only is an indentation in the adjoining layer eliminated, but the solid material also provides a stable and effective electrical interconnection between the metallic layers.

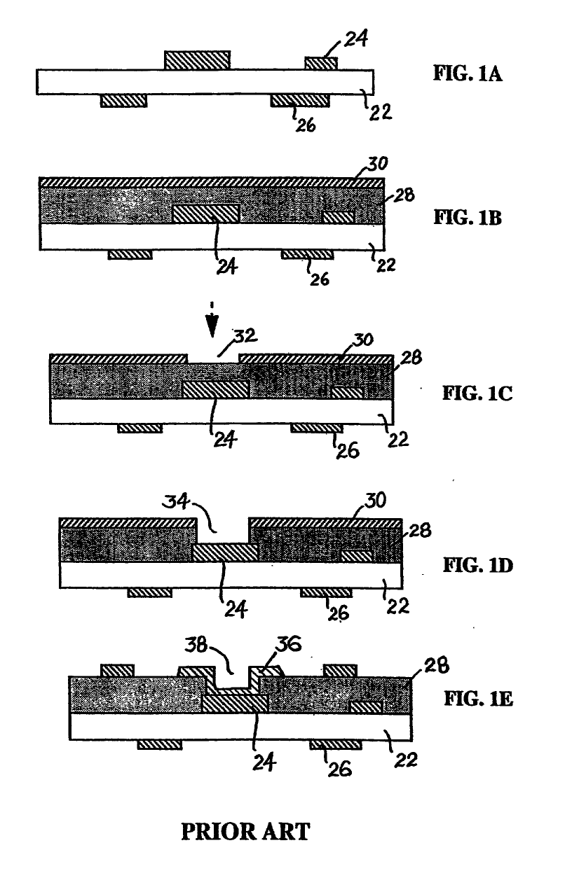

FIGS. 1A-1E shows in series a prior art process of producing an interconnect, and the resulting printed circuit board. In this example, a printed circuit board having two dielectric layers and three metallic layers is shown. When constructing a multi-layer printed circuit board, the layers are typically produced from the innermost to the outermost layers. FIG. 1A shows dielectric layer 22 cladded by lamination with metallic layers 24 and 26 on the two opposing surfaces. This may be produced by any conventional method such as photolithography and plating. FIG. 1B shows dielectric layer 28 and metallic layer 30 laid onto metallic layer 24. When laser drilling, layers 28 and 30 are typically a single product such as a copper coated resin film, in which layer 30 is a copper foil coated onto a polymeric resin dielectric layer 28. A CO₂ laser is typically used to drill the hole in the dielectric layer, wherein the hole is adapted for receiving the interconnection. As described above, the CO₂ laser effectively cuts through the polymeric resin but cannot cut through metal. Therefore, prior to drilling with a CO₂ laser, a mask is first used to protect metallic layer 30 and to expose the site on which the interconnection is to be made. Then conventional etching is performed such that the metallic coating at position 32 is removed, as shown in FIG. 1C. Laser drilling is then used to form hole 34, as shown in FIG. 1D. This is followed by the removal of a thin layer of resin using conventional methods such as plasma ablation or desmearing. These resin removal techniques are needed to ensure that metallic surface 24 is completely free of residual non-conducting resin. Then masking and electroplating are performed such that a metallic layer 36 is deposited on the wall of hole 34. Further photolithography, metal plating and etching may be performed as known in art to produce the desired printed circuit board.

Those skilled in the art will appreciate from a review of the above description and FIG. 1E that hole 34 is not completely filled using the conventional electroplating methods to produce the interconnection, and that indentation 38 is found. This can lead to problems such as rupturing or bubbling due to entrapment of air during lamination of the next layer. As mentioned above, the indentation 38 is commonly filled with electrically conductive epoxy or paste after electroplating, however, the difference in coefficients of expansion between the composite filler and the metallic wall 36 may result in cracks when subjected to temperature cycling in the environment in the subsequent assembly processes.

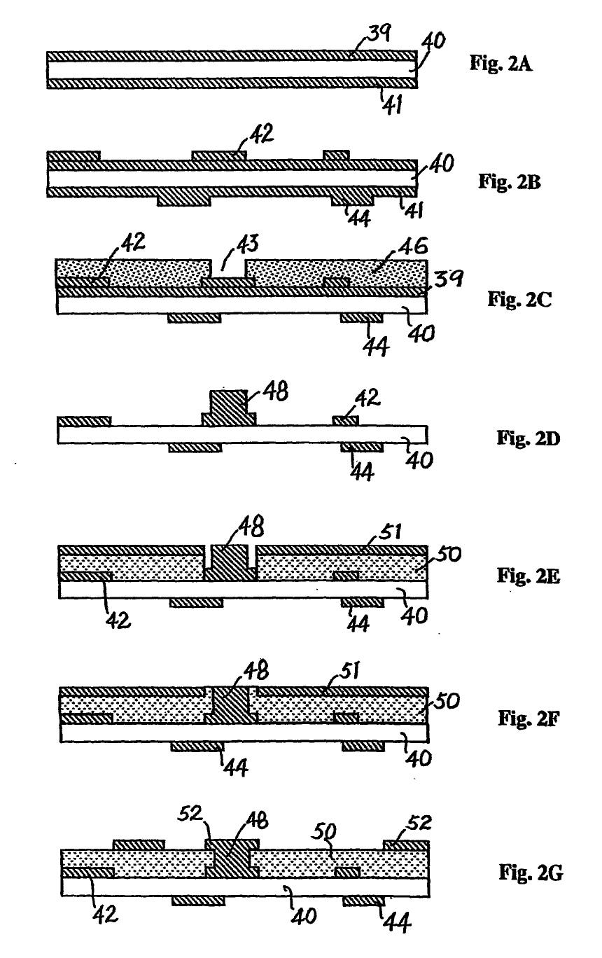

FIGS. 2A-2G show one method of producing a solid metallic interconnect according to the present invention, and a product produced using this method. FIG. 2A shows a dielectric layer 40 with two metallized surfaces 39 and 41. Conventional photolithography and plating are then performed to create circuitry 42 and 44 as shown in FIG. 2B. Before etching is performed on the base copper, layers 39 and circuitry 42 are covered with mask 46, exposing only position 43 where the solid metallic interconnection is to be made, as shown in FIG. 2C. Then electrolytic plating is performed such that a metallic post 48 is formed. Metals such as copper and/or nickel may be used for plating. An additional layer of etch-resistant metal such as gold may also be plated on the surface of the post to protect the post during the subsequent etching step. The mask is then removed and base copper 38 is etched using conventional methods as shown in FIG. 2D. As a further example, to produce the next layer of the board, a copper coated resin layer containing a layer of dielectric 50 and a layer of copper foil 51, with a pre-cut hole corresponding to the position of the metallic post (i.e. the interconnection) is aligned or registered with layer 42 as shown in FIG. 2E. This is followed by conventional curing, for example by heat pressing. During the lamination process, the resin flows into the space around post 48, and encloses it as it cures to form dielectric layer 50, as shown in FIG. 2F. Mechanical brushing is then applied to remove the thin film of resin covering the connective end of post 48. The tip of the metal post may also be shaped into a flat surface by brushing at this stage. Conventional lithography, plating, and etching are then performed to create the desired circuitry on metallic layer 52 (see FIG. 2G).

Although a copper coated resin (which is a combination of layers 50 and 51) is used as an example in FIG. 2F, the dielectric layer 50 alone may be used. For example, electroless plating may be employed later to create metallic layer 51 on the exposed surface of dielectric layer 50 which can then be used to create circuitry 51.

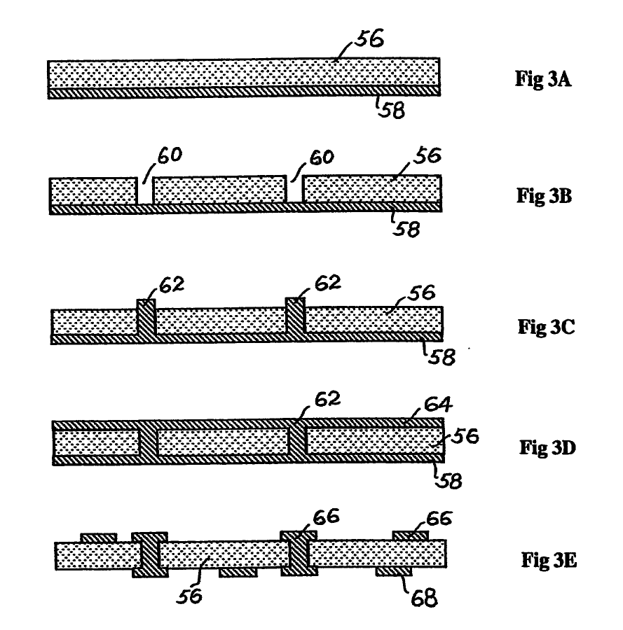

FIGS. 3A-3E show another method of producing a printed circuit board having a solid metallic interconnect according to the present invention. In this example, dielectric layer 56 is cladded with copper foil 58 as shown in FIG. 3A. Two holes 60 are then created by conventional laser technology. Electroplating is then performed such that two solid metallic interconnects 62 are created to interconnect metallic layer 58 and inside hole 60, as shown in FIG. 3C. Then brushing is performed to flatten the solid metallic interconnects 62, followed by electroplating to create a layer of base copper 64 on the upper surface of dielectric layer 56 as shown in FIG. 3D. Then standard photolithography and etching may be performed on metallized surfaces 64 and 58 to create circuitry 66 and 68 respectively as shown in FIG. 3E. Additional dielectric and metallic layers can then be added and additional solid interconnects may be created at various layers according to the teachings disclosed herein.

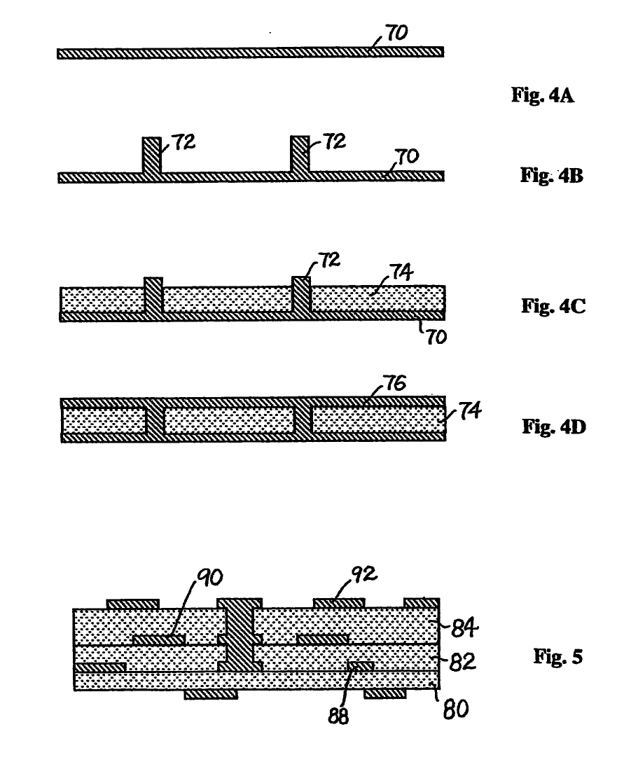

FIGS. 4A-4D show another alternate method of producing solid interconnects according to the present invention. In order to form the interconnect shown in FIG. 4D, first, a layer of copper foil 70 is taped onto a carrier and used as the starting material (see FIG. 4A). A photoresist is placed on foil 70 having holes at the locations corresponding to the solid metallic interconnects to be created (not shown). The solid metallic interconnects 72 are then created by conventional electrolytic plating, as shown in FIG. 4B. A layer of dielectric 74 is then layered above copper foil 70, as shown in FIG. 4C. In this example, no holes corresponding to the solid interconnect are precut or drilled. Instead, the solid metallic interconnect is allowed to pierce through the film of dielectric, e.g. a B-stage bond film with or without reinforcement. During heat pressing, the resin will flow around the interconnect and form a good seal around it, as shown in FIG. 4C. This is followed by brushing to flatten the upper surface of solid metallic interconnect and to remove any dielectric material from it. Electroplating can then be performed on dielectric layer 74, to create an additional metallic layer 76 on the upper surface of dielectric layer 74. Conventional photolithography and etching can then be performed on the metallic layers.

Instead of using a film-type of dielectric as described above for FIG. 4C, a wet type dielectric may also be used. This is achieved by spraying a layer of resin onto copper base 70. During the curing process, the resin will form around the solid interconnect in the same manner as the film-type resin. Brushing, shaping and polishing can then be performed on the solid interconnect as described above. The dielectric layers may be produced from wet or dry material, and the solid metallic interconnects may be produced on the same board connecting various metallic layers.

In accordance with the embodiments described above, all types of printed circuit board boards having solid interconnects may be produced. For example, additional dielectric and metallic layers may be added to create a printed circuit board with three core layers (80, 82 and 84) and four circuitrized metallic layers (86, 88, 90, and 92), and a solid metallic interconnect which connects metallic layers 88, 90 and 92 as shown in FIG. 5.

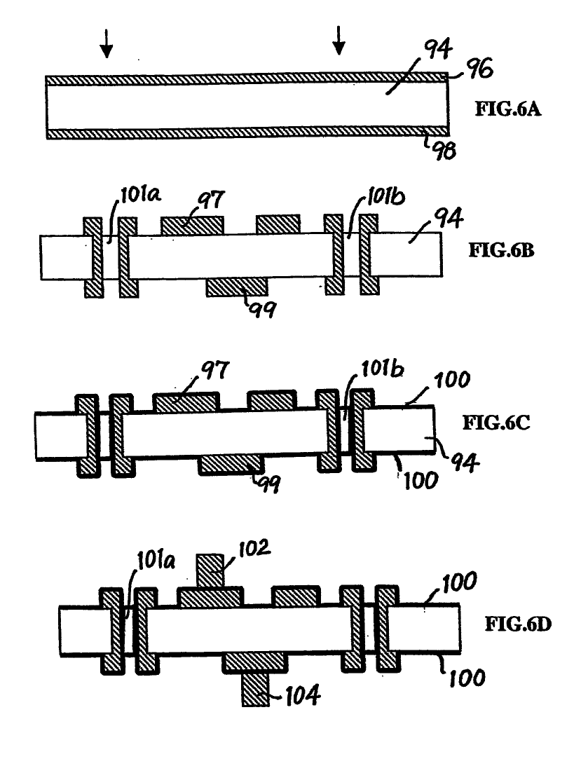

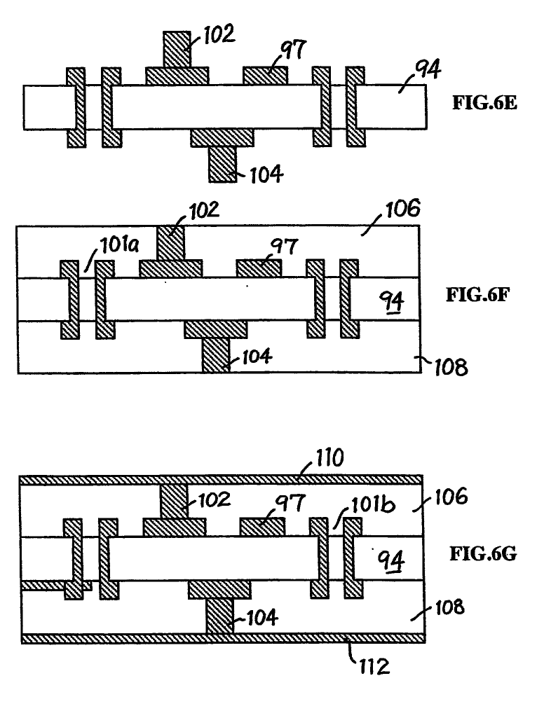

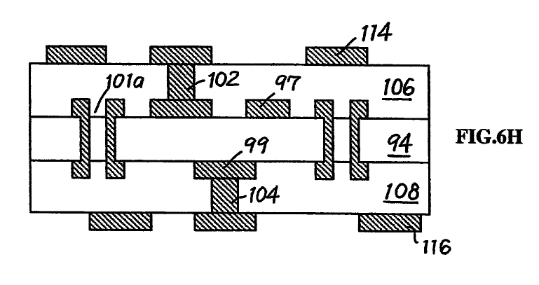

It should be understood that other printed circuit boards having solid interconnects spanning one or more dielectric core layers and connecting one or more metallic layers may be produced based on the teachings provided herewith. In a further example, to show a double-sided printed circuit board, FIG. 6A shows a core dielectric layer 94, with thin copper layers 96 and 98 laminated on its top and bottom surfaces. Two holes 101a and 101b are drilled through the core layer followed by plating using conventional photolithography to create the prescribed features 97 and 99 (FIG. 6B). A layer of copper 100 is then plated onto the top and bottom surfaces of the core layer, for example using electroplating (see FIG. 6C). Copper layer 100 is then used as the electrode of the electroplating of solid metallic interconnects 102 and 104 (FIG. 6D). The remaining surfaces are protected from being plated using a conventional photoresist and photolithography. After the solid interconnects 102 and 104 are created, the remaining copper layers 100 are removed by etching (FIG. 6E). A further second 106 and 108 layers of dielectric are then layered onto the first and second metallized layers 97 and 99 (FIG. 6F). The dielectric used here is preferably liquid dielectric. This is followed by removal of any dielectric material on the surface of solid interconnects 102 and 104 for example by brushing or desmearing. Two further thin copper layers 110 and 112 are then deposited onto the surface of dielectric layers 106 and 108 (FIG. 6G). Pattern plating is then repeated using conventional photolithography to produce a third and fourth metallized layers 114 and 116 (FIG. 6H). For additional layers, the steps in FIG. 6C to FIG. 6H can be repeated. The solid interconnects may be built through several layers if plating is repeated on the same position.

Those skilled in the art should appreciate that there is an enormous number of types of printed circuit boards that can be built using the teaching provided herein. It is contemplated that many changes and modifications may be made by one of ordinary skill in the art without departing from the spirit and the scope of the invention described.

This invention has been described herein in considerable detail in order to comply with the patent Statutes and to provide those skilled in the art with the information needed to apply the novel principles and to construct and use such specialized components as are required. However, it is to be understood that the invention can be carried out by specifically different equipment and devices, and that various modifications, both as to the equipment details and operating procedures, can be accomplished without departing from the scope of the invention itself.

What is claimed is:

1. A printed circuit board comprising:
a first metallic layer and a second metallic layer insulated by at least one dielectric layer, said first metallic layer and said second metallic layer electrically interconnected by at least one solid metallic interconnect.

2. A printed circuit board according to claim 1, wherein said solid metallic interconnect is made from a group consisting of plated gold, copper, nickel, alloy, and a combination thereof.

3. A printed circuit board according to claim 1, wherein at least one additional dielectric layer is laminated next to at least one of said first metallic layer and said second metallic layer.

4. A printed circuit board according to claim 1, wherein said first metallic layer and second metallic layer are insulated by at least two dielectric layers, said dielectric layers insulating at least one additional metallic layer.

5. A printed circuit board according to claim 1, wherein said first metallic layer and second metallic layer are insulated by at least two dielectric layers with at least one additional metallic layer therebetween, said additional metallic layer being electrically connected to said first metallic layer.

6. A printed circuit board according to claim 1, wherein said first metallic layer and second metallic layer are insulated by at least two dielectric layers with at least one additional metallic layer therebetween, said additional metallic layer electrically connected to said first metallic layer with at least one solid metallic interconnect.

7. A printed circuit board according to claim 1, wherein said first metallic layer and second metallic layer are insulated by at least two dielectric layers with at least one additional metallic layer therebetween, said additional metallic layer electrically connected to said first metallic layer and said second metallic layer.

8. A printed circuit board according to claim 1 wherein said first metallic layer and second metallic layer are insulated by at least two dielectric layers with at least one additional metallic layer therebetween, said additional metallic layer electrically connected to said first metallic layer and said second metallic layer by at least one solid metallic interconnect.

9. A method for producing a solid metallic interconnect in a printed circuit board including the steps of:
(a) protecting a first surface of a metallic layer with a protective layer such that the metallic surface corresponding to at least one interconnect is exposed; and
(b) electroplating on said exposed metallic surface of said metallic layer to form a solid metal post.

10. A method according to claim 9, wherein the height of said post is higher than the height of said interconnect.

11. A method according to claim 9, wherein said protective layer is a photoresist layer, and etching is performed after said plating step to remove said photoresist layer.

12. A method according to claim 9, wherein said protective layer is a photoresist layer, and said method further includes the steps of:
(c) etching to remove said photoresist layer;
(d) laminating a dielectric layer on said first surface;
(e) cleaning said top surface of said post to remove non-electrically conducting material;
(f) shaping said post to the desired shape and height;
(g) producing a second metallic layer on said dielectric layer opposite said metallic layer; and
(h) producing electric circuitry on said metallic layer and said first metallic layer whereby an electrical connection is created therebetween via said post.

13. A method according to claim 9, wherein said protective layer is a dielectric layer, and said method further includes the steps of:
(c) cleaning said top surface of said post to remove non-electrically conducting material;
(d) shaping said post to the desired shape and height;
(e) producing a second metallic layer on said dielectric layer opposite said metallic layer; and
(f) producing electric circuitry on said metallic layer and said first metallic layer whereby an electrical connection is created therebetween via said post.

14. A method according to claim 12, wherein said cleaning step comprises a plasma ablation process or a desmearing process and said shaping step comprises a mechanical brushing process.

15. A method according to claim 13, wherein said cleaning step comprises a plasma ablation process or a desmearing process and said shaping step comprises a brushing process.

16. A method according to claim 12, wherein said laminating step is performed by spraying a resin layer onto said first metal surface such that the post pierces through said film.

17. A method according to claim 12, wherein said laminating step is performed by laying a dielectric film onto said first surface.
